(19) United States
(12) Patent Application Publication
(10) Pub. No.: US 2014/0137917 A1
(43) Pub. Date: May 22, 2014

(54) THERMOELECTRIC MODULE WITH BI-TAPERED THERMOELECTRIC PINS

(71) Applicant: KING FAHD UNIVERSITY OF PETROLEUM AND, DHAHRAN (SA)

(72) Inventors: ABDULRAHMAN AL-MERBATI, KHOBAR (SA); Bekir Sami Yilbas, Dhahran (SA)

(73) Assignee: KING FAHD UNIVERSITY OF PETROLEUM AND MINERALS, DHAHRAN (SA)

(21) Appl. No.: 13/681,353

(22) Filed: Nov. 19, 2012

(51) Int. Cl. H01L 35/32; H01L 35/16

(52) U.S. Cl. CPC H01L 35/32; H01L 35/16
USPC 136/205; 136/238

(57) ABSTRACT

The thermoelectric module with bi-tapered thermoelectric pins is a semiconductor device configured as a thermoelectric power generator that has pins made of Bismuth Telluride that attach to a ceramic hot plate and a ceramic cold plate to form a thermoelectric module (TEM). The pins will include at least one N-doped pin and one P-doped pin. The bi-tapered pin structure of the TE pins exhibits low maximum thermal stress as predicted by thermal analysis, thereby maintaining thermal, electrical, and mechanical integrity of the TEM device.

### BACKGROUND OF THE INVENTION

1. Field of the Invention

The present invention relates to ThermoElectric Modules (TEMs), and particularly to a thermoelectric module with bi-tapered thermoelectric (TE) pins that exhibit low thermal stress while maintaining the plates in a stable mechanical configuration.

2. Description of the Related Art

A thermoelectric module (TEM) is a solid state device that can operate as a heat pump or as an electrical power generator. When a thermoelectric module is used as a heat pump, the thermoelectric module utilizes the Peltier effect to move heat. When a thermoelectric module is used to generate electricity, the thermoelectric module may be referred to as a thermoelectric generator (TEG). The TEG may be electrically connected to a power storage circuit, such as a battery charger, for storing electricity generated by the TEG.

N-type and P-type Bismuth Telluride thermoelectric pins are used in a thermoelectric generator. The semiconductor thermoelectric pins attach to both a heat plate and a cold plate, separating the two plates from each other. The heat difference between the opposing plates causes electrical potential to be developed between the N-type and the P-type Bismuth Telluride structures.

These thermoelectric generators operate between the high and low temperature sources, and the efficiency of the device increases with increasing temperature difference between the sources. However, thermal stress developed within the device limits temperature difference in practical applications of the device due to the shortening of the life cycle of the device. Although considerable research studies have been carried out to examine the thermodynamic performance of the thermoelectric device, thermal stress developed due to temperature gradients is given low attention. Additionally, material failure due to high stress-induced cracking prevents further operations of the device with expected performance. Consequently, investigation into thermal stress development in the thermoelectric device becomes essential.

Thus, a thermoelectric module with bi-tapered thermoelectric pins solving the aforementioned problems is desired.

### SUMMARY OF THE INVENTION

The thermoelectric module with bi-tapered thermoelectric pins is a semiconductor device configured as a thermoelectric power generator that has pins made of Bismuth Telluride that attach to a ceramic hot plate and a ceramic cold plate to form a thermoelectric module (TEM). The pins will include at least one N-doped pin and one P-doped pin. The bi-tapered pin structure of the TE pins exhibits low maximum thermal stress as predicted by thermal analysis, thereby maintaining thermal, electrical, and mechanical integrity of the TEM device.

These and other features of the present invention will become readily apparent upon further review of the following specification and drawings.

### BRIEF DESCRIPTION OF THE DRAWINGS

FIG. 1 is a perspective view of a thermoelectric module with bi-tapered thermoelectric pins according to the present invention.

FIG. 2 is a side view of the thermoelectric module of FIG. 1.

FIG. 3 is a thermal stress contour diagram for a thermoelectric module with bi-tapered thermoelectric pins according to the present invention.

Similar reference characters denote corresponding features consistently throughout the attached drawings.

### DETAILED DESCRIPTION OF THE PREFERRED EMBODIMENTS

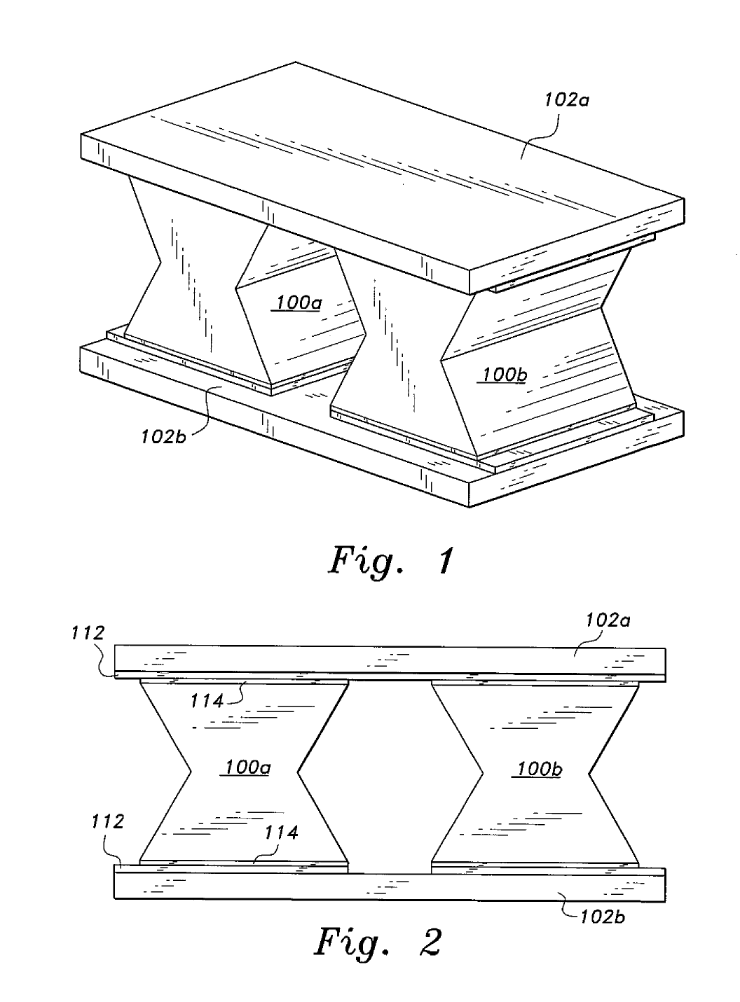

In the thermoelectric module with bi-tapered thermoelectric (TE) pins, the bi-tapered TE pins help to increase the life of the thermoelectric module (TEM) device by reducing thermal stress in the pins. As shown in FIGS. 1 and 2, the bi-tapered pins 100a and 100b attach to a ceramic hot plate 102a and a ceramic cold plate 102b. The bi-tapered pin structure of the TE pins 100a, 100b exhibits low maximum thermal stress, as predicted by thermal analysis, thereby maintaining thermal, electrical, and mechanical integrity of the TEM device. Each pin 100a, 100b has a top surface attachable to the ceramic hot plate 102a and a bottom surface attachable to the ceramic cold plate 102b. Rear and front support surfaces of the pin have substantially symmetrically opposing V-shaped chamfer cuts of approximately equal depth to create a forward facing side-to side laterally extending V-shaped channel on the front support surface and a rear facing side-to-side laterally extending V shaped channel on the rear support surface, resulting in the bi-tapered structure. The bi-tapered pin structure exhibits relatively low maximum thermal stress, as predicted by thermal analysis.

The temperature dependent properties are used in the analysis. The transient heat conduction equation considered is:

$$\frac{\partial }{\partial x} [ k ( T ) \frac{\partial T}{\partial x} ] + \frac{\partial }{\partial y} [ k ( T ) \frac{\partial T}{\partial y} ] + \frac{\partial }{\partial z} [ k ( T ) \frac{\partial T}{\partial z} ] - {c}_{p} ( T ) ρ \frac{\partial T}{\partial t} \qquad ( 1 )$$

The coupled thermal stress analysis require to identify the displacement-strain relations, which are expressed in dimensionless form as follows:

$$\begin{matrix}{\overline{ɛ}}_{xx} = \frac{\partial \overline{u}}{\partial \overline{x}} , {\overline{ɛ}}_{yy} = \frac{\partial \overline{v}}{\partial \overline{y}} , {\overline{ɛ}}_{zz} = \frac{\partial \overline{w}}{\partial \overline{z}} \\ and & ( 2 ) \\ {\overline{ɛ}}_{xy} = \frac{1}{2} ( \frac{\partial \overline{u}}{\partial \overline{y}} + \frac{\partial \overline{v}}{\partial \overline{x}} ) , \\ {\overline{ɛ}}_{yz} = \frac{1}{2} ( \frac{\partial \overline{v}}{\partial \overline{z}} + \frac{\partial \overline{w}}{\partial \overline{y}} ) , \\ {\overline{ɛ}}_{zx} = \frac{1}{2} ( \frac{\partial \overline{u}}{\partial \overline{z}} + \frac{\partial \overline{w}}{\partial \overline{x}} ) & ( 3 )\end{matrix}$$

An exact implementation of Newton's method involves a nonsymmetrical Jacobian matrix which is stress-strain relation in dimensionless form as is illustrated in the following matrix representation of the coupled equations:

$$\{ \begin{matrix}{\overline{σ}}_{xx} \\ {\overline{σ}}_{yy} \\ {\overline{σ}}_{zz} \\ {\overline{σ}}_{yz} \\ {\overline{σ}}_{zx} \\ {\overline{σ}}_{xy}\end{matrix} \} = \frac{\overline{E}}{( 1 + v ) ( 1 - 2 v )} \times [ \begin{matrix}1 - v & v & v & 0 & 0 & 0 \\ v & 1 - v & v & 0 & 0 & 0 \\ v & v & 1 - v & 0 & 0 & 0 \\ 0 & 0 & 0 & 1 - 2 v & 0 & 0 \\ 0 & 0 & 0 & 0 & 1 - 2 v & 0 \\ 0 & 0 & 0 & 0 & 0 & 1 - 2 v\end{matrix} ] \{ \begin{matrix}{\overline{ɛ}}_{xx} \\ {\overline{ɛ}}_{yy} \\ {\overline{ɛ}}_{zz} \\ {\overline{ɛ}}_{yz} \\ {\overline{ɛ}}_{zx} \\ {\overline{ɛ}}_{xy}\end{matrix} \} - \{ \begin{matrix}1 \\ 1 \\ 1 \\ 0 \\ 0 \\ 0\end{matrix} \} \frac{\overline{α} \overline{E} \overline{T}}{1 - 2 v} \qquad ( 4 )$$

Solving this system of equations requires the use of the unsymmetrical matrix storage and solution scheme. Furthermore, the mechanical and thermal equations are solved simultaneously.

The thermoelectric generator includes hot planar ceramic substrate 102a, cold planar ceramic substrate 102b, copper plates 112, and tin-Lead solder layers 114 securing upper contact surfaces and lower contact surfaces of the thermoelectric pins to hot 102a and cold 102b ceramic substrates, respectively, as shown in FIGS. 1 and 2. The thickness of the copper plate 112 is on the order of a fraction of millimeters, for example 0.12 mm, the thickness of solder layer 114 is on the order of a fraction of millimeter, for example 0.04 mm, and the thickness of ceramic substrate 102a and 102b is on the order of a fraction of millimeter, for example 0.34 mm. The size of the thermoelectric generator pins 100a and 100b is on the order of millimeter cube, for example 3 mm×3 mm×3 mm.

The thermal stress simulations assume that the thermoelectric pins 100a and 100b are made from Bi₂Te₃ (bismuth telluride). The thermal conductivity km, coefficient of linear thermal expansion a(T), specific heat capacity Cₚ(T), and modulus of elasticity E(T) are the function of temperature. Tables 1, 2, 3 and 4 give the typical values of a TEM module using Bi₂Te₃ pin material.

FIG. 1: Properties of Bi₂Te₃

| | Thermal Conductivity |
|---|---|
| Temperature (K) | (W/mK) |
| 325 | 0.93 |
| 375 | 0.9 |
| 425 | 0.91 |
| 475 | 0.95 |
| 525 | 1.1 |

FIG. 2: Properties of Bi₂Te₃

| | Thermal Expansion |
|---|---|
| Temperature (K) | Coefficient (−1/K) |
| 297 | 8.00E−06 |
| 304.3 | 1.01E−05 |
| 365 | 1.21E−05 |
| 451 | 1.24E−05 |
| 613 | 1.32E−05 |
| 793 | 1.33E−05 |
| 864 | 1.41E−05 |

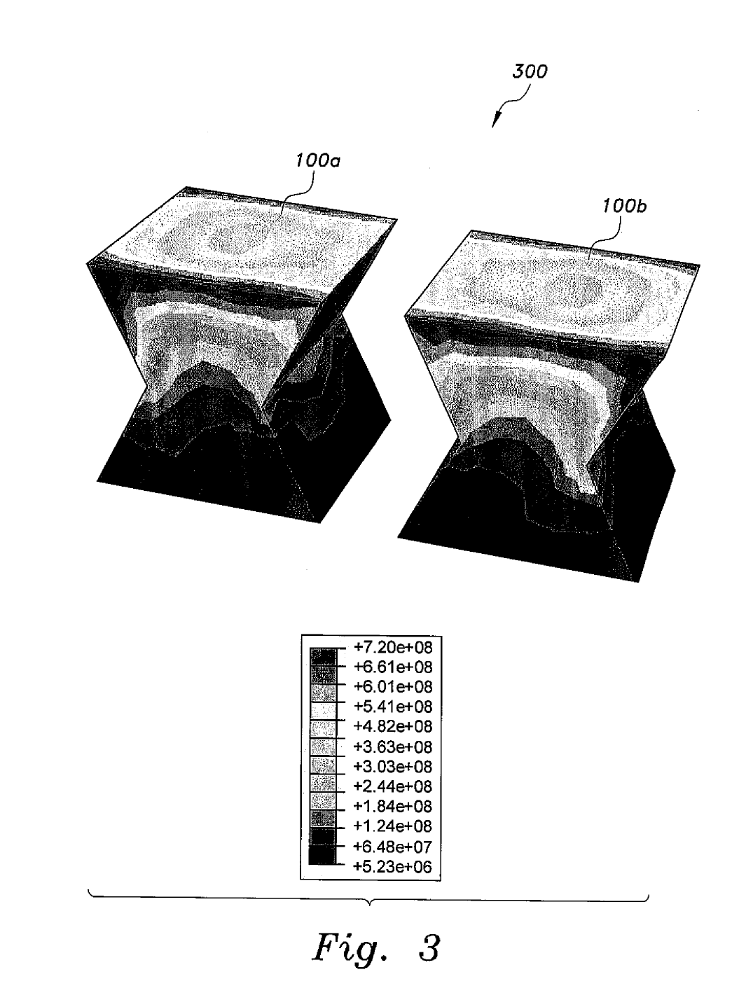

FIG. 3: Properties of Bi₂Te₃

| | Young's modulus | |
|---|---|---|
| Temperature (K) | (Pa) | Poisson's ratio |
| 200 | 6.5E+10 | 0.23 |
| 300 | 6.3E+10 | 0.23 |
| 400 | 6.2E+10 | 0.23 |
| 500 | 6.0E+10 | 0.23 |
| 600 | 5.9E+10 | 0.23 |

FIG. 4: Properties of Bi2Te3

| | |
|---|---|
| Specific Heat (J/kgK) | 154.4 |
| Density (kg/m3) | 7740 |
| Yield Stress (Pa) | 1.12E+08 |

FIG. 3 shows thermal stress contours in bi-tapered pins 100a and 100b for the thermoelectric module. The high stress region occurs locally in the pin, particularly at the edges of the pin, where the pin would be attached to the high temperature plate. The attainment of high stress is because of one or all of the following reasons: (1) high temperature gradient developed in this region gives to high thermal stress levels, and (2) the difference in thermal expansion coefficients due to the pin and the hot plate, which generates high stress levels at the interface location between the hot plate and the pin. Moreover, the low stress region in the pin extends towards the cold junction region. Maximum thermal stress predicted from the analysis for the bi-tapered TE pins 100a and 100b is approximately 0.720 GPa.

It is to be understood that the present invention is not limited to the embodiments described above, but encompasses any and all embodiments within the scope of the following claims.

1. A thermoelectric module with bi-tapered thermoelectric pins, comprising:
a hot ceramic plate;
a cold ceramic plate;
at least one P-doped bismuth telluride thermoelectric pin and at least one N-doped thermoelectric pin attached to and extending between the hot and cold ceramic plates, each of the pins having an elongate body having a hot plate attachment end, a cold plate attachment end, and a central region extending between the attachment ends, the pins having a flat front face, a flat rear face, and opposing side faces, the opposing side faces including upper and lower planar faces tapering inward from the hot plate and cold plate attachment ends to form a V-shaped dihedral angle, the thermoelectric module being configured as a thermoelectric power generating semiconductor device, wherein the at least one P-doped bismuth telluride thermoelectric pin and the at least one N-doped thermoelectric pin are each symmetric about a first plane passing through vertices of the respective V-shaped dihedral angles and parallel to said hot and cold ceramic plates, and are each further symmetric about a respective second plane extending centrally through each respective thermoelectric pin orthogonal to the first plane and to each of said hot and cold ceramic plates.

2. A first thermoelectric (TE) pin for a thermoelectric modular (TEM) power generating device, comprising:
substantially rectangular top and bottom contact surfaces having substantially equal contact areas;
rear and front support surfaces having substantially symmetrically opposing V-shaped chamfer cuts of approximately equal depth, said chamfer cuts creating a forward facing side-to side laterally extending V-shaped channel on the front support surface and a rear facing side-to-side laterally extending V-shaped channel on the rear support surface, wherein the first thermoelectric pin is symmetric about a first plane passing through vertices of the respective V-shaped chamfer cuts and parallel to said top and bottom contact surfaces, and is further symmetric about a second plane extending centrally through the first thermoelectric pin orthogonal to the first plane and to each of said top and bottom contact surfaces, the first thermoelectric in being composed of Bismuth Telluride semiconducting material;
wherein the first TE pin forms a bi-tapered structure.

3. The first thermoelectric (TE) pin according to claim 2, further comprising:
a cold ceramic plate;
a first copper electric conducting plate disposed on said cold ceramic plate;
a first solder layer disposed on said first copper electric conducting plate, said bottom contact surface of said first TE pin contacting said first solder layer, said first solder layer mechanically and electrically securing said bottom contact surface to said first copper electric conducting plate;
a hot ceramic plate;
a second copper electric conducting plate disposed on said hot ceramic plate; and
a second solder layer disposed on said second copper electric conducting plate, said top contact surface of said first TE pin contacting said second solder layer, said second solder layer mechanically and electrically securing said top contact surface of said first TE pin to said second copper electric conducting plate.

4. The first thermoelectric (TE) pin according to claim 3, further comprising a second bi-tapered TE pin attached between said cold and said hot plates secured by said first copper plate, said second copper plate, and solder layers in the same manner as said first TE pin, said second TE pin also being composed of Bismuth Telluride semiconducting material.
